(19) United States
(12) Patent Application Publication
(10) Pub. No.: US 2010/0243018 A1
(43) Pub. Date: Sep. 30, 2010

(54) METALLIZATION FOR ZINTL-BASED THERMOELECTRIC DEVICES

(75) Inventors: Billy Chun-Yip Li, Walnut, CA (US); Erik J. Brandon, Pasadena, CA (US); Vilupanur A. Ravi, Claremont, CA (US); Thierry Caillat, Pasadema, CA (US); Richard C. Ewell, Altadena, CA (US); Samad A. Firdosy, La Crescenta, CA (US); Jeff S. Sakamoto, East Lansing, MI (US)

Correspondence Address: CANADY & LORTZ LLP, 2540 HUNTINGTON DRIVE, SUITE 205, SAN MARINO, CA, 91108, US

(73) Assignee: California Institute of Technology, Pasadena, CA (US)

(21) Appl. No.: 12/749,491

(22) Filed: Mar. 29, 2010

Related U.S. Application Data
(60) Provisional application No. 61/164,325, filed on Mar. 27, 2009.

(51) Int. Cl. H01L 35/30; B32B 37/02; B32B 38/00

(52) U.S. Cl. 136/205; 156/60; 156/73.1

(57) ABSTRACT

A thermoelectric power generation device using molybdenum metallization to a Zintl thermoelectric material in a thermoelectric power generation device operating at high temperature, e.g. at or above 1000° C., is disclosed. The Zintl thermoelectric material may comprise Yb₁₄MnSb₁₁. A thin molybdenum metallization layer of approximately 5 microns or less may be employed. The thin molybdenum layer may be applied in a foil under high pressure, e.g. 1800 psi, at high temperature, e.g. 1000° C. The metallization layer may then be bonded or brazed to other components, such as heat collectors or current carrying electrodes, of the thermoelectric power generation device.

### CROSS-REFERENCE TO RELATED APPLICATIONS

This application claims the benefit under 35 U.S.C. §119(e) of the following U.S. provisional patent application, which is incorporated by reference herein:

U.S. Provisional Patent Application No. 61/164,325, filed Mar. 27, 2009, and entitled “METALLIZATION FOR Yb₁₄MnSb₁₁-BASED THERMOELECTRIC MATERIALS”, by Li et al. (Attorney Docket CIT-5332-P).

### STATEMENT OF GOVERNMENT RIGHTS

The invention described herein was made in the performance of work under a NASA contract, and is subject to the provisions of Public Law 96-517 (35 USC 202) in which the Contractor has elected to retain title.

### BACKGROUND OF THE INVENTION

1. Field of the Invention

This invention relates to thermoelectric devices. Particularly, this invention relates to a metallization for Zintl-based thermoelectric power generation devices, particularly those using Yb₁₄MnSb₁₁ (YMS).

2. Description of the Related Art

Thermoelectric materials exhibit the property of producing an electric voltage from an applied temperature differential across the material, the so-called thermoelectric effect or Seebeck effect. Accordingly, such materials may be used in thermoelectric devices to generate electrical power from a temperature differential. Such thermoelectric generators have been used to convert heat directly to electrical power for applications including isolated facilities or space applications. Depending upon the application, the applied heat may be naturally available or generated, e.g. by burning fuel or from a decaying radioisotope.

As mentioned, thermoelectric materials are known to provide a means for directly converting heat into electrical energy in a fully solid state device. Due to the nature of thermoelectric materials, power generating devices require a pairing of two different materials, typically comprised of highly doped narrow band gap semiconductors (one with an excess of n-type charge carriers, the other with an excess of p-type carriers) connected in a junction.

Prior art thermoelectric devices have featured materials such as silicon germanium, lead telluride, bismuth telluride or other related materials. To achieve greater device efficiency and greater specific power, however, new thermoelectric materials, are required in more complex combinations. One suitable material is found in the class of Zintl materials, particularly the compound p-type semiconductor Yb₁₄MnSb₁₁ (YMS), which has been demonstrated to have one of the highest zT values at 1000° C., a typical operational temperature of space-based radioisotope thermoelectric generators (RTGs).

For example, some thermoelectric power generation for deep space applications have employed SiGe thermoelectric materials generating electric power using a decaying radioisotope, e.g. plutonium 238, as a heat source, in an RTG. The fuel source and solid state nature of the devices afford exceptional service life and reliability, paramount considerations in space applications which offset the relatively low efficiency of such devices. Many working RTG devices for space applications have been developed and successfully employed. See e.g. Winter et al., “The Design of a Nuclear Power Supply with a 50 Year Life Expectancy: The JPL Voyager's SiGe MHW RTG,” IEEE AES Systems Magazine, April 2000, pp. 5-12; and U.S. Pat. No. 3,822,152, issued Jul. 2, 1974 to Kot, which are incorporated by reference herein.

Recent focus on renewable energy and increased energy efficiency has resulted in increased interest in thermoelectric materials and devices for applications such as automotive and industrial waste heat recovery. Zintl materials in particular have been studied for thermoelectric applications. A particular Zintl compound, Yb₁₄MnSb₁₁, has shown exceptional promise for thermoelectric power generation applications. See e.g. Brown et al., “Yb₁₄MnSb₁₁ New High Efficiency Thermoelectric Materials for Power Generation,” Chem. Mater., 18, 2006, 1873-1877, which is incorporated by reference herein. However, defining the properties of a particular material are only a first step in the development of a practical thermoelectric power generation device using that material.

SiGe has been well studied as a thermoelectric material as a result of previous RTG development. See e.g., Rowe, “Recent Advanced in Silicon-Germanium Alloy Technology and an Assessment of the Problems of Building the Modules for a Radioisotope Thermoelectric Generator,” Journal of Power Sources, 19 (1987), pp. 247-259; and “Silicon Germanium Thermoelectric Materials and Module Development Program,” ALO (2510)-T1, AEC Research and Development Rep, Cat. UC33, TID 4500, which are incorporated by reference herein. However, although the general configurations of previously developed SiGe thermoelectric power generation devices may be applicable, there are differences in the physical properties of Zintl materials and SiGe that demand new solutions in the development of a practical thermoelectric power generation devices using Zintl materials; the solutions for SiGe thermoelectric materials cannot be readily applied to Zintl thermoelectric materials.

Devising a suitable metallization and bonding scheme for a Zintl material such as Yb₁₄MnSb₁₁, however, is made difficult by the complex reactivity of its individual components. Since Yb₁₄MnSb₁₁ is an inorganic compound featuring chemical bonds with a mixture of covalent and ionic character, simple metallurgical diffusion bonding is difficult to implement. Furthermore, Sb reacts with most metals to form antimonide compounds with a wide range of stoichiometries. Although choosing metals which react to form high melting point antimonides could be employed to form a reaction bond, it is difficult to limit the reactivity of Sb in Yb₁₄MnSb₁₁ such that the electrode would not be completely consumed at an operating temperature at or above 1000° C. Mismatch in the coefficient of thermal expansion (CTE) of some antimonides (e.g., niobium antimonide) also limits the usefulness of such an approach.

In view of the foregoing, there is a need in the art for apparatuses and methods for applying metallization to Zintl materials such as Yb₁₄MnSb₁₁ in thermoelectric devices. There is particularly a need for such apparatuses and methods in Zintl-based thermoelectric devices operating at high temperatures, e.g. around or above 1,000 K. There is a need for such apparatuses and methods to improve the operating performance by efficiently conducting heat and electricity to and from the thermoelectric material. There is a need for such apparatuses and methods to operate for such thermoelectric devices in space applications. These and other needs are met by embodiments of the present invention as detailed hereafter.

### SUMMARY OF THE INVENTION

A thermoelectric power generation device using molybdenum metallization to a Zintl thermoelectric material in a thermoelectric power generation device operating at high temperature, e.g. at or above 1000° C., is disclosed. The Zintl thermoelectric material may comprise Yb₁₄MnSb₁₁. A thin molybdenum metallization layer of approximately 5 microns or less may be employed. The thin molybdenum layer may be applied in a foil under high pressure, e.g. 1800 psi, at high temperature, e.g. 1000° C. The metallization layer may then be bonded or brazed to other components, such as heat collectors or current carrying electrodes, of the thermoelectric power generation device.

A typical embodiment of the invention comprises a thermoelectric device having a Zintl thermoelectric material for generating electrical power from heat and at least one molybdenum metallization layer bonded to a surface of the Zintl thermoelectric material. When integrated into a thermoelectric device, the Zintl material generates power over a range of temperature differentials. The Zintl-based materials have the added benefit of being able to operate to temperatures at or above 1000° C. for extended periods. Typically, the Zintl thermoelectric material comprises Yb₁₄MnSb₁₁. The Zintl thermoelectric material may operate substantially in a vacuum and the heat for generating the electrical power may be generated by a decaying radioisotope.

In some embodiments, the molybdenum metallization layer may be ultrasonically cleaned prior to bonding to the Zintl thermoelectric material. The molybdenum metallization layer may be no more than approximately 5 μm thick.

In further embodiments, the molybdenum metallization layer may be bonded to the Zintl thermoelectric material under at least approximately 1800 psi. In addition, the molybdenum metallization layer may be bonded to the Zintl thermoelectric material substantially in a vacuum. The molybdenum metallization layer is bonded at approximately at least 1000° C. for at least 12 hours.

In some embodiments of the invention the thermoelectric device may include a heat collector for the thermoelectric device attached to the molybdenum metallization layer. Additionally, the thermoelectric device may include an electrode for the thermoelectric device attached to the molybdenum metallization layer.

In a similar manner, a typical method embodiment of the invention of forming metallization in a thermoelectric device, comprising the steps of providing a Zintl thermoelectric material for generating electrical power from heat at a temperature of at least 1000° C., and bonding at least one molybdenum metallization layer to a surface of the Zintl thermoelectric material. The method embodiment of the invention may be further modified consistent with the apparatus embodiments described herein.

### BRIEF DESCRIPTION OF THE DRAWINGS

Referring now to the drawings in which like reference numbers represent corresponding parts throughout:

FIG. 1 is a schematic diagram of an exemplary thermoelectric device employing a Zintl thermoelectric material with molybdenum metallization for both thermal and electrical conduction;

FIG. 2 shows a magnified image of molybdenum foil bonded to Yb₁₁MnSb₁₄ prior to annealing;

FIG. 3 shows a magnified cross section image of molybdenum bonded to Yb₁₁MnSb₁₄ after vacuum heat treatment for one week at 1000° C.; and

FIG. 4 is a flowchart of an exemplary method of forming metallization in a thermoelectric device.

### DETAILED DESCRIPTION OF THE PREFERRED EMBODIMENT

### 1. Overview

As previously mentioned, embodiments of the present invention are directed to forming metallization layers on Zintl thermoelectric materials, particularly Yb₁₁MnSb₁₄, operating at temperatures above 1000° C. A novel metallization layer for such Zintl thermoelectric materials may be formed with molybdenum bonded to a surface of the Zintl material. The molybdenum metallization layer can provide superior thermal and electrical conduction to and from the Zintl thermoelectric material. In addition to diffusion bonding of metals foils to the Zintl material, the molybdenum layer can be introduced by other methods (such as sputtering or evaporation) that result in a thin metal layer. A thermoelectric power generation device employing a Zintl thermoelectric material, such as Yb₁₁MnSb₁₄, with molybdenum metallization operating at temperatures of approximately 1000° C.) and possibly in a space application (i.e. in a vacuum environment) may achieve improved performance.

### 2. Metallization for Zintl Materials in Thermoelectric Devices

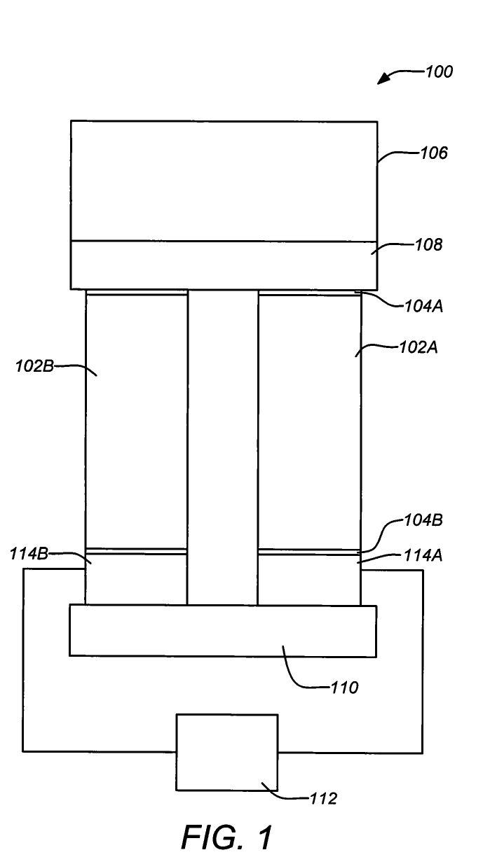

FIG. 1 is a schematic diagram of an exemplary thermoelectric device 100 employing two thermoelectric material elements 102A, 102B. The thermoelectric device 100 employs a Zintl thermoelectric material with molybdenum metallization for both thermal and electrical conduction. The thermoelectric material elements 102A, 102B of the thermoelectric device 100 generate electrical power directly from the applied thermal gradient between the heat collector 108 at one end and the cold shoe 110 at the other end. One of the thermoelectric material elements 102B acts as an n-type material providing excess electrons while the other thermoelectric material element 102A acts as an p-type material with deficient electrons.

At least one of the thermoelectric elements 102A, 102B comprises a Zintl thermoelectric material having at least one molybdenum metallization layer 104A, 104B. The molybdenum metallization layer 104A, 104B may be very thin, e.g. equal or less than 5 μm, to reduce thermomechanical stress within the Zintl element. Typically, a Zintl-based thermoelectric material such as Yb₁₁MnSb₁₄ may be employed for the p-type thermoelectric material element 102A, while another thermoelectric material, such as silicon germanium, lanthanum telluride or other n-type thermoelectric materials, may be employed for the n-type element 102B. However, those skilled in the art will appreciate that other combinations of thermoelectric materials may be employed for embodiments of the invention. Furthermore, each thermoelectric element 102A, 102B may comprise a combination of thermoelectric materials.

The two thermoelectric material elements 102A, 102B are thermally coupled in parallel between the heat collector 108 and cold shoe 110 but electrically isolated from one another. Heat is provided to the heat collector 108 from a coupled heat source 106, e.g. a decaying radioisotope such as plutonium 238 or any other suitable heat source capable of generating temperatures at or above 1000° C. The may be attached to the molybdenum metallization layer 104A at the hot end of the Zintl thermoelectric element 102A. Attachment between the heat collector 108 and the molybdenum metallization layer 104A may be achieved through diffusion bonding or brazing or any other suitable technique known to provide a conductive joint between the molybdenum and the material of the heat collector 108. Representative heat collectors can include graphite, nickel, silicon or any other materials which can be bonded to the thermoelectric elements, electrodes and/or metallization layers and which exhibit sufficient thermal conductivity and stability at the operating temperature of the device. The molybdenum layer 104A affords a stable, low contact resistance metallization for terminating the Zintl thermoelectric element 102A, thereby facilitating effective joining to other device elements such as electrodes and/or heat collectors, at both the hot and cold ends.

In contrast, the cold shoe 110 at the opposing end may include a radiator for rejecting heat to enhance the temperature differential across the thermoelectric material elements 102A, 102B. Electrical power is yielded from an electrical series connection across the two thermoelectric material elements 102A, 102B at electrodes 114A, 114B. The electrode 114A is attached to the molybdenum metallization layer 104B bonded to cold end of the Zintl thermoelectric element 102A. Attachment between the electrode 114A and the molybdenum metallization layer 104B may be achieved through diffusion bonding or brazing or any other suitable technique known to provide a conductive joint between the molybdenum and the material of the electrode 114A. Example electrode materials include copper, nickel and their related alloys. Typically, the electrical power is coupled to a power system 112 which may include a regulator and/or battery subsystems as known in the art.

It should be noted that the thermoelectric device 100 depicted in FIG. 1 is not to scale and presents only a generalized thermoelectric power generation device. The thermoelectric device 100 is just one example configuration of an embodiment of the invention utilizing an alumina coating sublimation suppression barrier of a Zintl thermoelectric material. Those skilled in the art will appreciate that the general configurations of previously developed thermoelectric power generation devices, e.g. SiGe and other RTGs, but with a Zintl thermoelectric element having molybdenum metallization layers 104A, 104B. For example, a practical power generation device may employ multiple stages (each like the single stage shown in the figure) coupled together to produce more power. In addition, the Zintl thermoelectric material elements 102A, 102B may also include other materials, e.g. to facilitate electrical connection to the power system 112 and electrical isolation, e.g. graphite barriers may be employed in the element stack. The heating element 106 need not be directly adjacent to the heat collector 108 but may only be radiatively coupled to the heat collector 108 instead.

It should also be noted that embodiments of the invention are not restricted to thermoelectric power generation devices, but may be applied to any application (e.g., possibly thermoelectric coolers and heaters as well) employing a Zintl thermoelectric material such as Yb₁₁MnSb₁₄ operating a temperatures at or above 1000° C. In addition, embodiments of the invention are not restricted to space applications in a vacuum environment. Embodiments of the invention may be employed with other environments surrounding the Zintl thermoelectric material. For example, some applications may utilize an Ar environment surrounding the thermoelectric material.

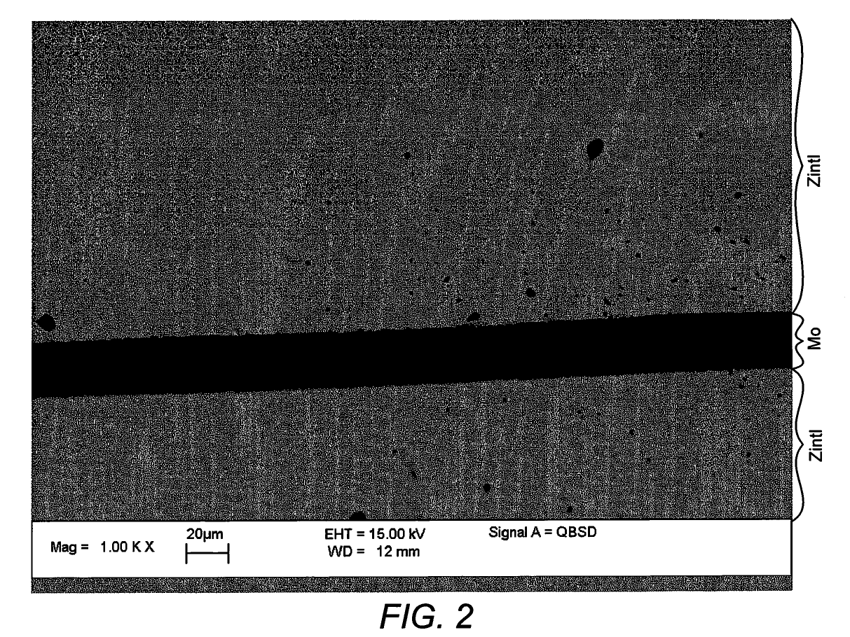

FIG. 2 shows a magnified image of molybdenum foil bonded to Yb₁₁MnSb₁₄ prior to annealing. An exemplary metallization process may employ a five micron molybdenum foil that has been suitably prepared by ultrasonic cleaning and etching. A typical method for cleaning may comprise etching of the molybdenum foil with a solution of approximately two parts hydrofluoric acid to three parts nitric acid to forty-five parts water (by volume). The molybdenum foil may be dipped for 5-10 seconds in the etchant solution, followed by extensive rinsing with water.

The prepared foil may then be bonded to a consolidated Yb₁₁MnSb₁₄ form under the application of heat and pressure. For example, one set of conditions that can successfully form a stable metallization bond is the use of approximately 1800 psi of pressure, applied at 1000° C. for 12 hours, under vacuum. Typical diffusion bonding runs are performed in an evacuated chamber (approximately 5×10⁻⁵ Torr), heated with graphite elements. The necessary bonding loads/pressures can be achieved through the application of appropriately sized fixed weights or a properly calibrated spring-loaded push rod and holding fixture applied over the foil on the thermoelectric element. However, a controllable hydraulic press ram may also be used to apply the proper pressure and provide an additional degree of automation as will be understood by those skilled in the art. Use of thin film molybdenum coatings or other known techniques for applying or bonding thin metal layers may also be employed as alternative processes as will be appreciated by those skilled in the art. These processes include, but are not limited to, physical deposition techniques such as sputtering or evaporation, plasma coating or chemical vapor deposition using appropriate precursors. When employing either diffusion bonding of metals or coating methods, the goal is to achieve a thin (typically <10 μm) metallization layer to minimize thermo-mechanical stresses.

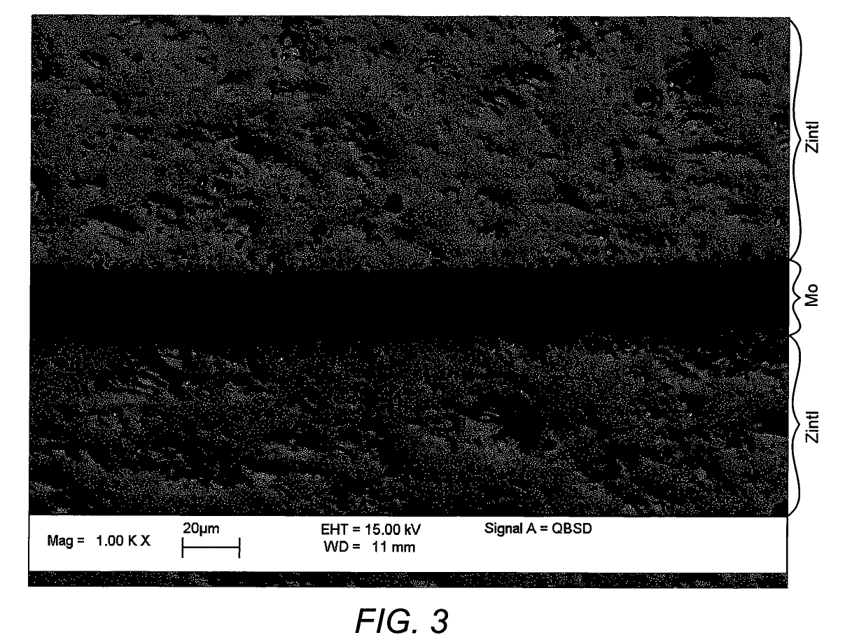

FIG. 3 shows a magnified cross section image of molybdenum bonded to Yb₁₁MnSb₁₄ after vacuum heat treatment for one week at 1000° C. The resulting metallization layer typically exhibits a contact resistance of less than or equal to approximately 25 μΩ-cm². The contact is thermally stable with respect to Yb₁₁MnSb₁₄, exhibiting no de-bonding or increase in contact resistance after a 1000° C. vacuum heat treatment for approximately two weeks as shown in FIG. 3. As previously mentioned, the molybdenum metallization layer may be attached to other components of a thermoelectric power generation device, such as heat collectors or current carrying electrodes. The other component may be attached to the metallization through bonding or brazing or any other known metal attachment technique suitable for molybdenum.

The specific nature of the interaction between molybdenum and Yb₁₁MnSb₁₄ should be further investigated. The diffusion of molybdenum metal atoms over some length scale into the Yb₁₁MnSb₁₄ material is likely involved in the bonding process. However, no evidence for the formation of compounds has been detected. Although there are known molybdenum antimonide compounds, such compounds are not thermodynamically stable at the bonding temperature and no evidence for their formation may be observed using electron dispersive spectroscopy (EDS). One skilled in the art will note this metallization scheme avoids the formation of a brittle interlayer between the metal and thermoelectric element, that is typical of bonded interfaces between metals and thermoelectric materials. These brittle regions often lead to failure of devices, and avoiding their formation is a key consideration in the design of such interfaces.

### 3. Forming Metallization in a Zintl-Based Thermoelectric Device

Embodiments of the invention also encompass a method of forming a metallization on a Zintl thermoelectric material, e.g. Yb₁₁MnSb₁₄. As discussed above, a metallization of some type is typically required for Zintl-based thermoelectric power generation devices in order to both thermally conduct heat to the Zintl thermoelectric material at one end and also to electrically conduct power from the Zintl thermoelectric material.

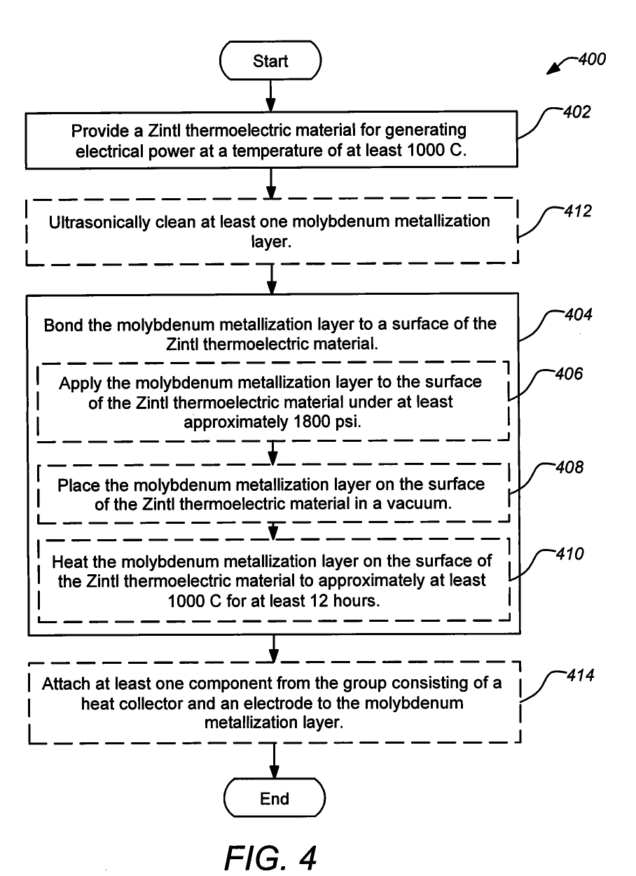

FIG. 4 is a flowchart of an exemplary method 400 of forming metallization in a thermoelectric device. The method 400 begins with an operation 402 of providing a Zintl thermoelectric material for generating electrical power at a temperature of at least 1000° C. Typically, the Zintl thermoelectric material may comprise Yb₁₁MnSb₁₄. Next in operation 404, at least one molybdenum metallization layer is bonded to a surface of the Zintl thermoelectric material. Typically, the molybdenum metallization layer has a thickness of no more than 5 μm.

Bonding operation 402 may include a number of optional sub-operations. For example, the bonding may comprise a sub-operation 406 of applying the molybdenum metallization layer to the surface of the Zintl thermoelectric material under at least approximately 1800 psi. In sub-operation 408, the molybdenum metallization layer on the surface of the Zintl thermoelectric material may be placed in a vacuum. In sub-operation 410, the molybdenum metallization layer on the surface of the Zintl thermoelectric material is heated to approximately at least 1000 C for at least 12 hours. Note that the sub-operations 406-410 are indicated by dashed outlines residing within bonding operation 402 in FIG. 4. Those skilled in the art will appreciate that bonding the molybdenum metallization layer to the Zintl thermoelectric material may be achieved through other known processes as well.

The method 400 of forming a sublimation suppression barrier may also be further modified by other optional operations. For example, the method 400 may further include the optional operation 412 of ultrasonically cleaning the molybdenum metallization layer. In addition, the method 400 may also include the optional operation 414 of attaching at least one component, a heat collector or an electrode, to the molybdenum metallization layer. The molybdenum metallization layer can efficiently conduct heat or electricity in the thermoelectric power generation device. The method 400 may also be further enhanced through optional operations consistent with the described parameters and any known techniques of semiconductor device manufacture and Zintl material processing as will be understood by those skilled in the art. Note that the optional operations 412, 414 are indicated by dashed outlines in FIG. 4.

This concludes the description including the preferred embodiments of the present invention. The foregoing description including the preferred embodiment of the invention has been presented for the purposes of illustration and description. It is not intended to be exhaustive or to limit the invention to the precise forms disclosed. Many modifications and variations are possible within the scope of the foregoing teachings. Additional variations of the present invention may be devised without departing from the inventive concept as set forth in the following claims.

What is claimed is:

1. A thermoelectric device, comprising:
a Zintl thermoelectric material for generating electrical power from heat; and
at least one molybdenum metallization layer bonded to a surface of the Zintl thermoelectric material;
wherein the Zintl thermoelectric material generates the electrical power at a temperature of at least 1000° C.

2. The thermoelectric device of claim 1, wherein the Zintl thermoelectric material comprises Yb₁₄MnSb₁₁.

3. The thermoelectric device of claim 1, wherein the molybdenum metallization layer is ultrasonically cleaned prior to bonding to the Zintl thermoelectric material.

4. The thermoelectric device of claim 1, wherein the molybdenum metallization layer is no more than approximately 5 μm thick.

5. The thermoelectric device of claim 1, wherein the molybdenum metallization layer is bonded to the Zintl thermoelectric material under at least approximately 1800 psi.

6. The thermoelectric device of claim 1, wherein the molybdenum metallization layer is bonded to the Zintl thermoelectric material substantially in a vacuum.

7. The thermoelectric device of claim 1, wherein the molybdenum metallization layer is bonded at approximately at least 1000° C. for at least 12 hours.

8. The thermoelectric device of claim 1, further comprising a heat collector for the thermoelectric device attached to the molybdenum metallization layer.

9. The thermoelectric device of claim 1, further comprising an electrode for the thermoelectric device attached to the molybdenum metallization layer.

10. A method of forming metallization in a thermoelectric device, comprising the steps of:
providing a Zintl thermoelectric material for generating electrical power from a temperature differential with a hot side temperature of at least 1000° C.; and
bonding at least one molybdenum metallization layer to a surface of the Zintl thermoelectric material.

11. The method of claim 10, wherein the Zintl thermoelectric material comprises Yb₁₄MnSb₁₁.

12. The method of claim 10, further comprising ultrasonically cleaning the molybdenum metallization layer prior to bonding to the Zintl thermoelectric material.

13. The method of claim 10, wherein the molybdenum metallization layer is no more than approximately 5 μm thick.

14. The method of claim 10, wherein the molybdenum metallization layer is bonded to the Zintl thermoelectric material under at least approximately 1800 psi.

15. The method of claim 10, wherein the molybdenum metallization layer is bonded to the Zintl thermoelectric material substantially in a vacuum.

16. The method of claim 10, wherein the molybdenum metallization layer is bonded at approximately at least 1000° C. for at least 12 hours.

17. The method of claim 10, further comprising attaching a heat collector for the thermoelectric device to the molybdenum metallization layer.

18. The method of claim 10, further comprising attaching an electrode for the thermoelectric device to the molybdenum metallization layer.

19. A thermoelectric device, comprising:
a Zintl thermoelectric material means for generating electrical power from a temperature differential, with temperature hot side temperature of at least 1000° C.; and
a molybdenum metallization layer means for attaching at least one component of the thermoelectric device, the molybdenum metallization layer means bonded to a surface of the Zintl thermoelectric material.

20. The thermoelectric device of claim 19, wherein the Zintl thermoelectric material comprises Yb₁₄MnSb₁₁.

21. The thermoelectric device of claim 19, wherein the component comprises a heat collector for the thermoelectric device.

22. The thermoelectric device of claim 19, wherein the component comprises an electrode for the thermoelectric device.
